(19) United States
(12) Patent Application Publication
(10) Pub. No.: US 2014/0089766 A1
(43) Pub. Date: Mar. 27, 2014

(54) APPARATUS AND METHOD FOR LOW DENSITY PARITY CHECK (LDPC) ENCODING

(71) Applicant: ELECTRONICS AND TELECOMMUNICATIONS RESEARCH INSTITUTE, Daejeon (KR)

(72) Inventors: In Ki LEE, Daejeon (KR); Deock Gil OH, Daejeon (KR); Ji Won JUNG, Busan (KR); Min Hyuk KIM, Busan (KR)

(73) Assignee: ELECTRONICS AND TELECOMMUNICATIONS RESEARCH INSTITUTE, Daejeon (KR)

(21) Appl. No.: 14/031,279

(22) Filed: Sep. 19, 2013

(30) Foreign Application Priority Data
Sep. 27, 2012 (KR) 10-2012-0107982

(51) Int. Cl. H03M 13/13

(52) U.S. Cl. CPC H03M 13/13
USPC 714/776

(57) ABSTRACT

Provided is a low density parity check (LDPC) encoding apparatus and method that may store M registers each including N bits, obtain N×M parity bits by performing a partial parallel operation an N×M number of times with respect to the M registers, and mutually invert subsequent N parity bits periodically, based on previous parity bits for each Nth parity bit of the N×M parity bits, respectively.

### CROSS-REFERENCE TO RELATED APPLICATION

This application claims the benefit of Korean Patent Application No. 10-2012-0107982, filed on Sep. 27, 2012, in the Korean Intellectual Property Office, the disclosure of which is incorporated herein by reference.

### BACKGROUND

1. Field of the Invention

The present invention relates to a high speed encoding apparatus and method of a low density parity check (LDPC) encoder in a radio communication system.

2. Description of the Related Art

A radio communication system providing a high quality service may have a relatively inadequate channel environmental conditions, for example, fading, non-linearity, and the like, when compared to a wired communication system. Accordingly, an error control scheme excellent in error correction may be necessary.

Error correcting codes applicable to broadband satellite broadcasting may include concatenated codes for a Digital Video Broadcasting-Satellite (DVB-S), turbo codes for Digital Video Broadcasting-Return Channel by Satellite (DVB-RCS), and low density parity check (LDPC) codes for Digital Video Broadcasting-Satellite-Second Generation (DVB-S2).

The concatenated codes may obtain a relatively high code gain, and produce high performance in a channel error control scheme that receives attention in relation to a radio communication system, when compared to conventional technologies. The turbo codes producing similar performance were developed in 1993.

However, since the turbo codes are inapplicable to a 300 mega bits per second (Mbps) or higher broadband transmission system, there is an inevitable demand for an encoder which is efficient in high speed data transmission and produces excellent performance. Accordingly, an LDPC encoding scheme suggested in DVB-S2 may be appropriate for 100 Mbps or higher super-high satellite broadcasting technologies for providing a super-high quality multichannel realistic broadcasting service all over the country.

The LDPC codes may have a channel capacity close to a limit of a channel capacity applied to DVB-S2, based on European satellite broadcasting standards. Accordingly, when the LDPC codes are used for an operation of an encoder, an encoding complexity may be relatively low when compared to the turbo codes, a great distance characteristic may prevent an error floor phenomenon, and high-speed processing may be possible with full parallel processing.

However, since a general LDPC encoding apparatus may require an operation for accumulating a previous value and a current value in an encoding process, the full parallel processing may be impossible.

### SUMMARY

According to an aspect of the present invention, there is provided a low density parity check (LDPC) encoding apparatus, including a storage unit to store M registers each including N bits, an operation unit to obtain N×M parity bits by performing a partial parallel operation an N×M number of times with respect to the M registers, and an inversion unit to mutually invert subsequent N parity bits periodically, based on previous parity bits for each Nth parity bit of the N×M parity bits, respectively.

N may correspond to a value of “360,” and M may correspond to a value of “90”.

The operation unit may include an extraction unit to extract at least one of the M registers based on a first index list, and a permutation unit to permute N bits included in the extracted register, using a second index list.

The extraction unit may extract a respective register corresponding to at least one first index value included in the first index list.

The permutation unit may place a bit of a sequence corresponding to at least one second index value included in the second index list as a first bit, and arrange at least one subsequent bit sequentially.

The storage unit may store the N×M parity bits in groups of N parity bits at respective addresses.

The inversion unit may extract N parity bits at a last address among the respective addresses, and mutually invert subsequent N parity bits based on a last parity bit of the extracted N parity bits, respectively.

An initial parity bit of the previous parity bits may correspond to an Nth parity bit.

The inversion unit may mutually invert the subsequent N parity bits when the previous parity bits have predetermined values.

The predetermined values may correspond to a value of “1”.

According to another aspect of the present invention, there is also provided an LDPC encoding method, including storing M registers each including N bits, obtaining N×M parity bits by performing a partial parallel operation an N×M number of times with respect to the M registers, and mutually inverting subsequent N parity bits periodically, based on previous parity bits for each Nth parity bit of the N×M parity bits, respectively.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating a configuration of a low density parity check (LDPC) encoding apparatus according to an embodiment of the present invention;

FIG. 2 is a diagram illustrating an H matrix structure for LDPC encoding according to an embodiment of the present invention;

FIG. 3 is a diagram illustrating an LDPC encoding algorithm structure according to an embodiment of the present invention;

FIG. 4 is a block diagram illustrating a configuration of an operation unit according to an embodiment of the present invention;

FIG. 5 is a diagram illustrating a first index list according to an embodiment of the present invention;

FIG. 6 is a diagram illustrating a second index list according to an embodiment of the present invention; and

FIG. 7 is a flowchart illustrating an LDPC encoding method according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

When it is determined that a detailed description is related to a related known function or configuration which may make the purpose of the present invention unnecessarily ambiguous in the description of the present invention, such a detailed description will be omitted. Also, terminologies used herein are defined to appropriately describe the exemplary embodiments of the present invention and thus may be changed depending on a user, the intent of an operator, or a custom. Accordingly, the terminologies must be defined based on the following overall description of this specification.

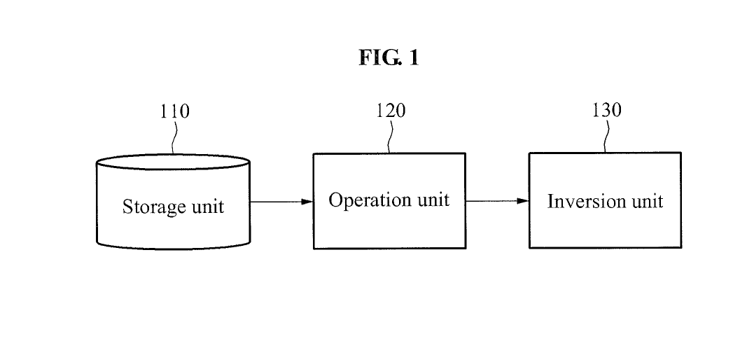

FIG. 1 is a block diagram illustrating a configuration of a low density parity check (LDPC) encoding apparatus according to an embodiment of the present invention.

Referring to FIG. 1, the LDPC encoding apparatus may include a storage unit 110, an operation unit 120, and an inversion unit 130. The storage unit may store M registers each including N bits. The operation unit 120 may obtain N×M parity bits, by performing a partial parallel operation an N×M number of times with respect to the M registers. The inversion unit 130 may mutually invert subsequent N parity bits periodically, based on previous parity bits for each Nth parity bit of the N×M parity bits, respectively.

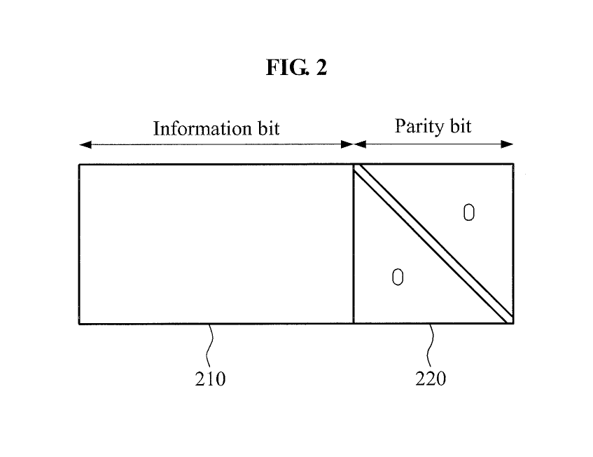

FIG. 2 is a diagram illustrating an H matrix structure for LDPC encoding according to an embodiment of the present invention.

Referring to FIG. 2, XX may include an H matrix of Digital Video Broadcasting-Satellite-Second Generation (DVB-S2) LDPC codes. The H matrix may include an information bit 210 corresponding to information bits, and a parity part 220 corresponding to parity bits. In the information bit 210, a position of “1” may be distributed variously depending on a code rate. In the parity bit 220, the position of “1” may be fixed in a stepped form, as shown in FIG. 1.

Although the DVB-S2 LDPC may be designed to perform a partial parallel operation 360 times, an operation for accumulating a previous value and a current value may be required in an encoding process and thus, performing the partial processing may be difficult.

According to an embodiment of the present invention, an LDPC encoding apparatus may perform a partial parallel operation for a predetermined number of bits with respect to a process prior to an accumulator operation, and mutually invert parity bits based on a result of performing the operation, thereby operating codes at a high speed.

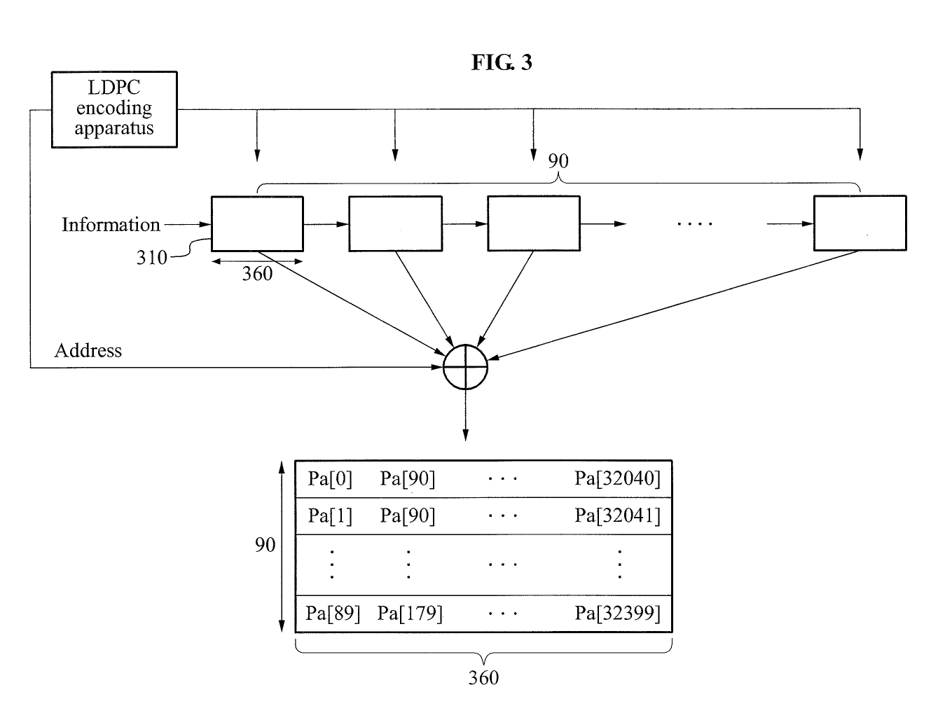

FIG. 3 is a diagram illustrating an LDPC encoding algorithm structure according to an embodiment of the present invention.

Referring to FIG. 3, an LDPC encoding apparatus may store M registers 310, each including N bits, and obtain N×M parity bits by performing a partial parallel operation an N×M number of times with respect to the M registers 310.

For ease of understanding and description, N may correspond to a value of “360” and M may correspond to a value of “90”.

For example, all information bits may be stored in groups of 360 bits sequentially in registers. When a code rate corresponds to 1/2, a number of registers each including 360 information bits may correspond to “90”. When all of the information bits are stored in the 90 registers, the LDPC encoding apparatus may perform a parity operation with respect each information bit, based on a first index list and a second index list.

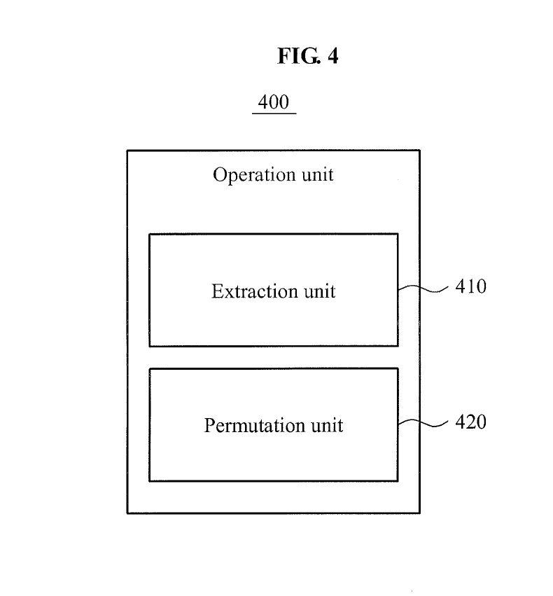

FIG. 4 is a block diagram illustrating a configuration of an operation unit 400 according to an embodiment of the present invention.

Referring to FIG. 4, the operation unit 440 may include an extraction unit 410 to extract at least one of M registers based on a first index list, and a permutation unit 420 to permute N bits included in the extracted register, using a second index list.

The extraction unit 410 may extract a respective register corresponding to at least one first index value included in the first index list. The permutation unit 420 may place a bit of a sequence corresponding to at least one second index value included in the second index list as a first bit, and arrange at least one subsequent bit sequentially.

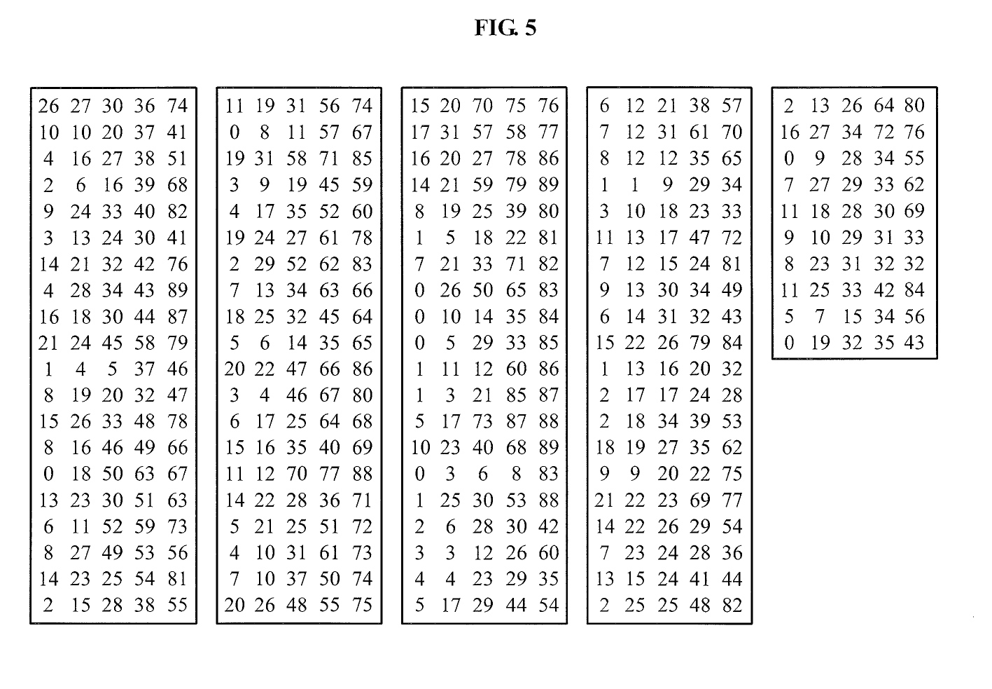

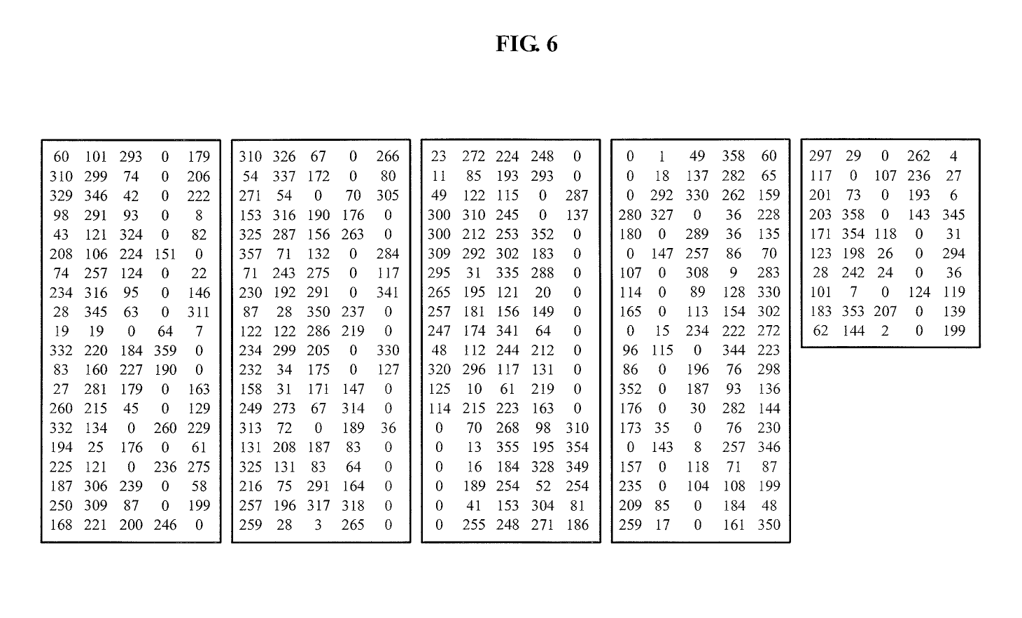

FIG. 5 is a diagram illustrating a first index list according to an embodiment of the present invention, and FIG. 6 is a diagram illustrating a second index list according to an embodiment of the present invention.

Referring to FIGS. 5 and 6, at least one first index value with respect to a register may be stored in the first index list, and the second index list may indicate N bits included in a resister selected by a selected first index value. In particular, the second index list may indicate permutation values of 360 data included in the register selected by the first index value.

For example, an LDPC encoding apparatus may retrieve first index values of “26, 27, 30, 36, 74” from the first index list, and retrieve second index values of “60, 101, 293, 0, 179” from the second index list. The LDPC encoding apparatus may extract a 26th register, a 27th register, a 30th register, a 36th register, and a 74th register, among the registers of FIG. 3, based on the retrieved index values, and perform a permutation task with respect to the extracted registers, respectively. In particular, the LDPC encoding apparatus may perform the permutation for a 60th bit of the 26th register to be placed first, and for a 59th bit of the 26th register to be placed last. Similarly, the LDPC encoding apparatus may perform the permutation for a 101st bit of the 27th register, a 293rd bit of the 30th register, a 0th bit of the 36th register, and a 179th bit of the 74th register, respectively, to be placed first.

The LDPC encoding apparatus may perform a parallel operation with respect to all 360 bits for each register. When an operation for a first row is completed, a parity bit Pa0 may be obtained, and sequentially, parity bits Pa90, Pa180, Pa270, . . . , Pa32040 may be obtained, as shown in FIG. 3.

In order to obtain subsequent parity bits based on previous parity bits, the LDPC encoding apparatus may store the 360 parity bits at a first address of a storage unit, and store the 360 parity bits in a register capable of storing 360 bits. In particular, the storage unit may store N×M parity bits in groups of N parity bits, at respective addresses.

The LDPC encoding apparatus may iterate the foregoing process 90 times, complete the parity operation for the information bits, and obtain the parity bits Pa0 through Pa89 shown in FIG. 3.

When the LDPC encoding apparatus extracts 360 parity bits at a last address of the storage unit, a parity bit Pa89, among the extracted parity bits, may correspond to data for which all operations are performed. However, although Paₙ=Paₙ⊕Paₙ₋₁ is to be performed, the operation may be performed improperly with respect to a parity bit Pa90 and subsequent parity bits. Accordingly, values of parity bits other than the parity bit Pa89 may be imperfect.

The LDPC encoding apparatus may extract, using the inversion unit, N parity bits at a last address, among the respective addresses, and mutually invert subsequent N parity bits based on a last parity bit of the extracted N parity bits, respectively. In this instance, an initial parity bit of the previous parity bits may correspond to an Nth parity bit.

When the previous parity bits have predetermined values, the LDPC encoding apparatus may mutually invert, using the inversion unit, the subsequent N parity bits, respectively. In this instance, the predetermined values may correspond to a value of “1”.

The parity bit operation may be performed through an exclusive OR operation of a bit operation. For example, when the parity bit Pa89 corresponds to a value of “1,” the LDPC encoding apparatus may invert all parity bits from Pa90 to Pa179. In addition, when the parity bit Pa179 corresponds to a value of “1,” the LDPC encoding apparatus may invert all parity bits from Pa180 to Pa269.

In such a logic operation, the LDPC encoding apparatus may iterate the sequential process a total of 359 times, with respect to the 360 parity bits extracted at the last address of the storage unit, thereby operating a very last parity bit. Here, the sequential process may refer to the process of inverting the parity bit Pa179 when the parity bit Pa89 corresponds to a value of “1,” inverting the parity bit Pa269 when the parity bit Pa179 corresponds to a value of “1,” and the like.

When the operation for the very last parity bit is completed, the LDPC encoding apparatus may extract parity bits at the first address of the storage unit again, and invert or not invert the 360 parity bits, respectively.

q clocks may be used for an operation with respect to initial information bits, and 359 clocks may be used for an operation with respect to last parity bits. Here, q may correspond to 90 when a code rate corresponds to 1/2. In addition, the LDPC encoding process may be performed using a total of 2q+358+α clocks when q−1 clocks are used through the process of retrieving addresses of the storage unit. In this instance, a denotes a number of clocks used for varied operations, and reading/writing of the storage unit.

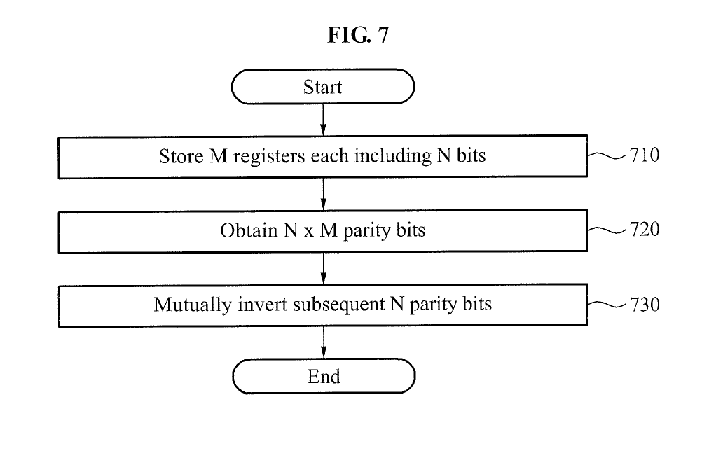

FIG. 7 is a flowchart illustrating an LDPC encoding method according to an embodiment of the present invention.

Referring to FIG. 7, in operation 710, an LDPC encoding apparatus may store M registers each including N bits. In operation 720, the LDPC encoding apparatus may obtain N×M parity bits by performing a partial parallel operation an N×M number of times with respect to the M registers. In operation 730, the LDPC may mutually invert subsequent N parity bits periodically, based on previous parity bits for each Nth parity bit of the N×M parity bits, respectively.

According to an embodiment of the present invention, there is provided an LDPC encoding apparatus and method capable of partial parallel processing.

According to an embodiment of the present invention, a giga-class high speed encoder may be implemented by performing a clock operation at a high speed.

The above-described exemplary embodiments of the present invention may be recorded in computer-readable media including program instructions to implement various operations embodied by a computer. The media may also include, alone or in combination with the program instructions, data files, data structures, and the like. Examples of computer-readable media include magnetic media such as hard disks, floppy disks, and magnetic tape; optical media such as CD ROM discs and DVDs; magneto-optical media such as floptical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention, or vice versa.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A low density parity check (LDPC) encoding apparatus, comprising:
a storage unit to store M registers each comprising N bits;
an operation unit to obtain N×M parity bits by performing a partial parallel operation an N×M number of times with respect to the M registers; and
an inversion unit to mutually invert subsequent N parity bits periodically, based on previous parity bits for each Nth parity bit of the N×M parity bits, respectively.

2. The apparatus of claim 1, wherein N corresponds to a value of “360,” and M corresponds to a value of “90”.

3. The apparatus of claim 1, wherein the operation unit comprises:
an extraction unit to extract at least one of the M registers based on a first index list; and
a permutation unit to permute N bits included in the extracted register, using a second index list.

4. The apparatus of claim 3, wherein the extraction unit extracts a respective register corresponding to at least one first index value included in the first index list.

5. The apparatus of claim 3, wherein the permutation unit places a bit of a sequence corresponding to at least one second index value included in the second index list as a first bit, and arranges at least one subsequent bit sequentially.

6. The apparatus of claim 1, wherein the storage unit stores the N×M parity bits in groups of N parity bits at respective addresses.

7. The apparatus of claim 6, wherein the inversion unit extracts N parity bits at a last address among the respective addresses, and mutually inverts subsequent N parity bits based on a last parity bit of the extracted N parity bits, respectively.

8. The apparatus of claim 1, wherein an initial parity bit of the previous parity bits corresponds to an Nth parity bit.

9. The apparatus of claim 1, wherein the inversion unit mutually inverts the subsequent N parity bits when the previous parity bits have predetermined values.

10. The apparatus of claim 9, wherein the predetermined values correspond to a value of “1”.

11. A low density parity check (LDPC) encoding method, comprising:
storing M registers each comprising N bits;
obtaining N×M parity bits by performing a partial parallel operation an N×M number of times with respect to the M registers; and
mutually inverting subsequent N parity bits periodically, based on previous parity bits for each Nth parity bit of the N×M parity bits, respectively.

12. The method of claim 11, wherein N corresponds to a value of “360,” and M corresponds to a value of “90”.

13. The method of claim 11, wherein the obtaining comprises:
extracting at least one of the M registers based on a first index list; and
permuting the N bits included in the extracted register, using a second index list.

14. The method of claim 13, wherein the obtaining further comprises extracting a respective register corresponding to at least one first index value included in the first index list.

15. The method of claim 13, wherein the obtaining further comprises placing a bit of a sequence corresponding to at least one second index value included in the second index list as a first bit, and arranging at least one subsequent bit sequentially.

16. The method of claim 11, further comprising:
storing the N×M parity bits in groups of N parity bits at respective addresses.

17. The method claim 16, wherein the inverting comprises:
extracting N parity bits at a last address among the respective addresses; and
mutually inverting subsequent N parity bits based on a last parity bit of the extracted N parity bits, respectively.

18. The method of claim 11, wherein an initial parity bit of the previous parity bits corresponds to an Nth parity bit.

19. The method of claim 11, wherein the inverting comprises inverting the subsequent N parity bits, respectively, when the previous parity bits have predetermined values.

20. The method of claim 19, wherein the predetermined values correspond to a value of “1”.
